(19) United States
(12) Patent Application Publication
(10) Pub. No.: US 2015/0228845 A1
(43) Pub. Date: Aug. 13, 2015

(54) III NITRIDE SEMICONDUCTOR LIGHT EMITTING DEVICE AND METHOD FOR MANUFACTURING THE SAME

(71) Applicant: DOWA ELECTRONICS MATERIALS CO., LTD., Tokyo (JP)

(72) Inventors: Yoshitaka Kadowaki, Akita-shi (JP); Tatsunori Toyota, Akita-shi (JP)

(21) Appl. No.: 14/423,348

(22) PCT Filed: Aug. 30, 2013
(86) PCT No.: PCT/JP2013/005138

§ 371 Date: Feb. 23, 2015

(30) Foreign Application Priority Data
Sep. 3, 2012 (JP) 2012-193312

(51) Int. Cl. H01L 33/00; H01L 33/38; H01L 33/20; H01L 33/32; H01L 33/12

(52) U.S. Cl. CPC H01L 33/0025; H01L 33/325; H01L 33/12; H01L 33/007; H01L 33/20; H01L 33/382; H01L 33/385; H01L 33/387; H01L 2933/0016

(57) ABSTRACT

A III nitride semiconductor light emitting device achieves improved light output power while reducing forward voltage. A III nitride semiconductor light emitting device according to the present invention includes, in the following order, a p-side electrode, a p-type III nitride semiconductor layer, a light emitting layer, an n-type III nitride semiconductor layer, and a buffer layer including an undoped III nitride semiconductor layer. An exposed portion is provided on the buffer layer. An n-side electrode is provided continuously on the n-type III nitride semiconductor layer, exposed in the exposed portion, and the buffer layer. The n-side electrode includes a plurality of contact portions in contact with the n-type III nitride semiconductor layer, and the contact portions are electrically interconnected on the buffer layer.

### TECHNICAL FIELD

The present invention relates to a III nitride semiconductor light emitting device and a method for manufacturing the same. The present invention relates in particular to a III nitride semiconductor light emitting device that achieves improved light output power while reducing forward voltage.

### BACKGROUND

Generally, group III-V semiconductors composed of a compound of a Group III element and a Group V element are widely used in devices such as a light emitting diode (LED).

A group III nitride semiconductor using Al, Ga, In, or the like as the group III element and using N as the group V element has a high melting point and high dissociation pressure for nitrogen, making bulk single crystal growth difficult. Furthermore, since there are no conductive single crystal substrates that are large-caliber and inexpensive, formation generally proceeds by growth on a sapphire substrate.

A sapphire substrate is insulating, however, so that current does not flow, and hence conventionally the following horizontal structure is adopted. A portion is removed from a light emitting structure laminate, in which an n-type III nitride semiconductor layer, an active layer (light emitting layer), and a p-type III nitride semiconductor layer are grown in this order on a sapphire substrate, in order to expose the n-type III nitride semiconductor layer. An n-type electrode and a p-type electrode are then disposed respectively on the exposed n-type III nitride semiconductor layer and the p-type III nitride semiconductor layer, and current is applied horizontally.

Against this background, a lift-off method has been studied in recent years. A buffer layer including an undoped III nitride semiconductor layer, such as an AlN layer, is formed on the sapphire substrate with a lift-off layer therebetween. On the buffer layer, a light emitting structure laminate including, in this order, an n-type III nitride semiconductor layer, a light emitting layer, and a p-type III nitride semiconductor layer is formed, and a p-side electrode is formed on the p-type III nitride semiconductor layer. The lift-off layer is then selectively dissolved by chemical etching for separation (lift-off) from the sapphire substrate. Subsequently, removing the buffer layer and forming an n-side electrode on the exposed n-type III nitride semiconductor layer yields an LED chip with a vertical structure in which the light emitting structure laminate is sandwiched by a pair of electrodes (see JP 2010-171420 A (PTL 1)). Until now, a buffer layer that includes an undoped III nitride semiconductor layer and is exposed by removal of the lift-off layer has thus been removed for formation of the n-side electrode.

### CITATION LIST

### Patent Literature

PTL 1: JP 2010-171420 A

The light emitting structure laminate in a III nitride semiconductor is typically thin, measuring a few microns. When including an Al composition III nitride semiconductor layer with a high emission wavelength, such as a 200 nm to 350 nm deep ultraviolet LED, the laminate is particularly thin. When forming a support member to maintain strength on the p-type III nitride semiconductor layer, subsequently separating the n-type III nitride semiconductor layer side from the sapphire substrate by the lift-off method, and then removing the buffer layer, at least a portion of the thin n-type III nitride semiconductor layer needs to be etched due to the precision of removal. Otherwise, it is difficult to expose the surface of the n-type III nitride semiconductor layer to obtain good ohmic contact. Therefore, also in a light extraction surface other than the electrode formation surface, the n-type III nitride semiconductor layer that remains as a light emitting device becomes thin, and the inventors considered that removing all of the buffer layer is disadvantageous for light extraction. In other words, in an LED chip yielded by the lift-off method, the inventors considered that light output power could be further improved and the forward voltage lowered by utilizing the buffer layer.

The present invention provides a III nitride semiconductor light emitting device that achieves improved light output power while reducing forward voltage and a method for manufacturing the same.

### SUMMARY

The inventors intensively studied a method for effectively using the buffer layer that is removed as above. The inventors discovered that the light output power is high and the forward voltage is low in a III nitride semiconductor light emitting device in which, on a buffer layer including an undoped III nitride semiconductor layer remaining after lift-off, an exposed portion of an n-type III nitride semiconductor layer is formed by removing a portion of the buffer layer from the lift-off side, and in the exposed portion, a plurality of independent contact portions where an n-side electrode is in contact with the n-type III nitride semiconductor layer are established. Specifically, primary features of the present invention are as follows.

A III nitride semiconductor light emitting device according to the present invention comprises a first electrode; a first conductivity type III nitride semiconductor layer connected to the first electrode; a light emitting layer provided on the first conductivity type III nitride semiconductor layer; a second conductivity type III nitride semiconductor layer provided on the light emitting layer; a buffer layer including an undoped III nitride semiconductor layer provided on the second conductivity type III nitride semiconductor layer; and a second electrode including a plurality of independent contact portions and electrically connecting the contact portions, the contact portions being in contact with the second conductivity type III nitride semiconductor layer exposed by removing a portion of the buffer layer, a portion of the second electrode being provided on the buffer layer.

In the present invention, the undoped III nitride semiconductor layer is preferably an MN layer.

In the present invention, the second electrode preferably includes the contact portions, a pad portion provided on the buffer layer, and a wiring portion connecting the contact portions and the pad portion.

In the present invention, an insulating layer positioned directly below the second electrode on a portion of a surface of the first conductivity type III nitride semiconductor layer facing the first electrode is preferably further included.

A method for manufacturing a III nitride semiconductor light emitting device according to the present invention comprises: (a) forming, sequentially on a growth substrate, a buffer layer containing an undoped III nitride semiconductor layer, a second conductivity type III nitride semiconductor layer, a light emitting layer, and a first conductivity type III nitride semiconductor layer; (b) forming a first electrode on the first conductivity type III nitride semiconductor layer; (c) removing the growth substrate to expose the buffer layer; (d) removing a portion of the buffer layer exposed in step (c) to expose a portion of the second conductivity type III nitride semiconductor layer; and (e) forming a second electrode continuously on the second conductivity type III nitride semiconductor layer exposed in step (d) and the buffer layer, the second electrode including a plurality of independent contact portions and electrically connecting the contact portions, the contact portions being in contact with the second conductivity type III nitride semiconductor layer.

In this case, the undoped III nitride semiconductor layer is preferably an MN layer.

According to the present invention, a III nitride semiconductor light emitting device that achieves improved light output power while reducing forward voltage and a method for manufacturing the same are provided.

### BRIEF DESCRIPTION OF THE DRAWINGS

The present invention will be further described below with reference to the accompanying drawings, wherein:

FIG. 1 is a top perspective view of a III nitride semiconductor light emitting device 100 according to the present invention;

FIG. 2 is a cross-sectional diagram along the A-A line in FIG. 1;

FIG. 3 is a top view of FIG. 1;

FIG. 4 is a cross-sectional diagram of another III nitride semiconductor light emitting device 200 according to the present invention;

FIG. 5 is a top view of another III nitride semiconductor light emitting device 300 according to the present invention;

FIG. 6 is a cross-sectional diagram along the B-B line in FIG. 5;

FIG. 7 is a top view of another III nitride semiconductor light emitting device 400 according to the present invention;

FIG. 8 is a modification to FIG. 7;

FIGS. 9(A) to 9(F) are cross-sectional diagrams illustrating a method of manufacturing the III nitride semiconductor light emitting device 100 according to the present invention;

FIGS. 10(A) to 10(C) are top views respectively of FIGS. 7(D) to 7(F);

FIG. 11 is a graph illustrating the light output power (Po) when applying a current of 0 mA to 300 mA to Examples 1 and 2 and Comparative Examples 1 and 2;

FIG. 12 is a graph illustrating the forward voltage (Vf) when applying a current of 0 mA to 300 mA to Examples 1 and 2 and Comparative Examples 1 and 2;

FIG. 13 is a top perspective view of a III nitride semiconductor light emitting device 500 in Comparative Example 1; and

FIG. 14 is a cross-sectional diagram along the F-F line in FIG. 13.

### DETAILED DESCRIPTION

The following describes the present invention in detail with reference to the drawings. In the present disclosure, constituent elements that are common to the III nitride semiconductor light emitting device according to the present invention and the III nitride semiconductor light emitting device of the comparative examples are, as a general rule, labeled with reference numbers having the same last two digits, and description thereof is not repeated. As a method for removing a growth substrate, the lift-off method to separate the growth substrate is used. The case of a chemical lift-off method using an etchable lift-off layer is described as an example.

III Nitride Semiconductor Light Emitting Device 100

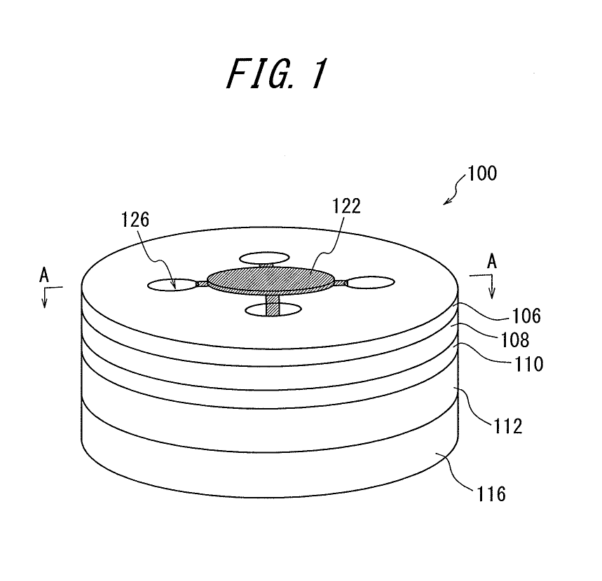

With reference to FIGS. 1 to 3, the III nitride semiconductor light emitting device 100 (also referred to below simply as a “light emitting device” 100) according to an embodiment of the present invention is described below.

As illustrated in FIG. 1, the light emitting device 100 includes a p-side electrode 116 as a first electrode, a III nitride semiconductor layer 112, which is p-type as the first conductivity type, on the p-side electrode 116 (referred to below simply as the “p-layer”), a light emitting layer 110 provided on the p-layer 112, a III nitride semiconductor layer 108, which is n-type as the second conductivity type, on the light emitting layer 110 (referred to below simply as the “n-layer”), and a buffer layer 106, which includes an undoped III nitride semiconductor layer, provided on the n-layer 108.

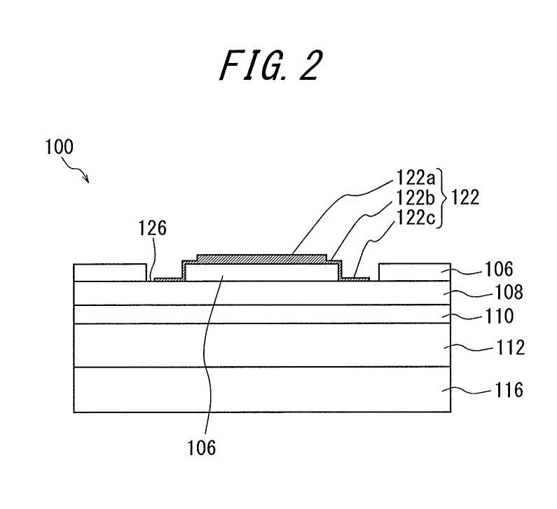

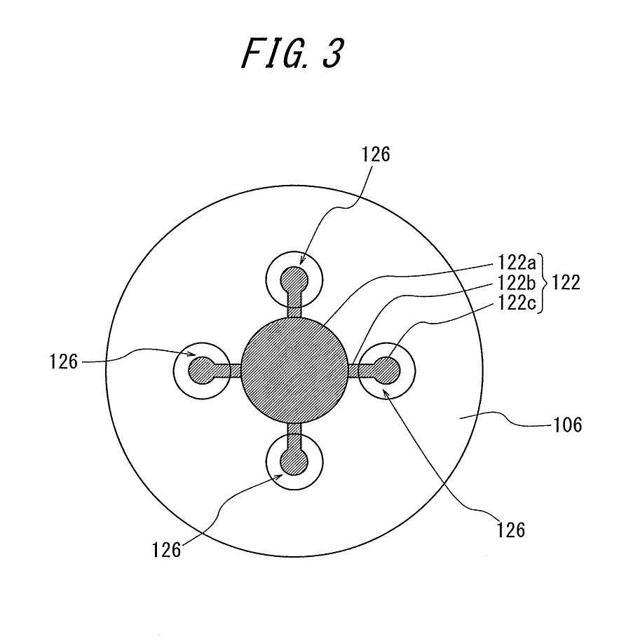

The characteristic structure of Embodiment 1 of the present invention is as follows. As illustrated in FIGS. 1 to 3, the buffer layer 106 includes a plurality of exposed portions 126 (for example, four) that expose a portion of the n-layer 108. As illustrated in FIGS. 2 and 3, the n-side electrode 122, which is the second electrode, is provided continuously on the n-layer 108, exposed in the exposed portions 126, and the buffer layer 106. The n-side electrode 122 is formed by contact portions 122c in contact with the n-layer 108 in the exposed portions 126, a pad portion 122a provided on the buffer layer 106, and wiring portions 122b connecting the contact portions 122c and the pad portion 122a. In other words, in the exposed portions 126, the n-side electrode 122 includes a plurality, four in this embodiment, of independent contact portions 122c in contact with the n-layer 108, and the contact portions 122c are electrically interconnected on the buffer layer 106 by the wiring portions 122b.

By maintaining the contact portions 122c independent on the n-layer 108 while interconnecting the contact portions 122c electrically on the buffer layer 106 by the wiring portions 122b, the light emitting device 100 according to the present invention for example can supply current from the pad portion 122a collectively to the contact portions 122c. The inventors discovered that removing only the portions of the buffer layer 106 where the contact portions 122c between the n-layer 108 and the n-side electrode 122 are to be provided and then providing the plurality of contact portions 122c achieves improved light output power while reducing forward voltage.

On the other hand, as in Comparative Example 1 described below, even when removing only the portion of the buffer layer 106 where the contact portion is to be provided, if the contact portion is provided continuously on the n-layer, i.e. if a plurality of contact portions are not provided, then the effects of improved light output power and reduced forward voltage are not achieved. While the exact reason is unknown, it is considered that by the contact portion being continuous, only the contact portion near the pad portion becomes the origin of current diffusion, making it easy for current to concentrate around pad portion, which limits the spread of current. It is also thought that light from a position directly below the pad portion, where current is concentrated and output increases, is easily blocked by the large pad portion. By contrast, when dividing the contact portion into a plurality of portions on the n-layer, as in the present invention, it is thought that light output power increases and forward voltage is reduced because the area of the contact portions near the pad portion is limited, making it easier for positions directly below the contact portions spread far from the pad portion to become the origin of current diffusion and thereby suppressing the concentration of current around the pad portion, and because more light is extracted without being blocked by the electrode.

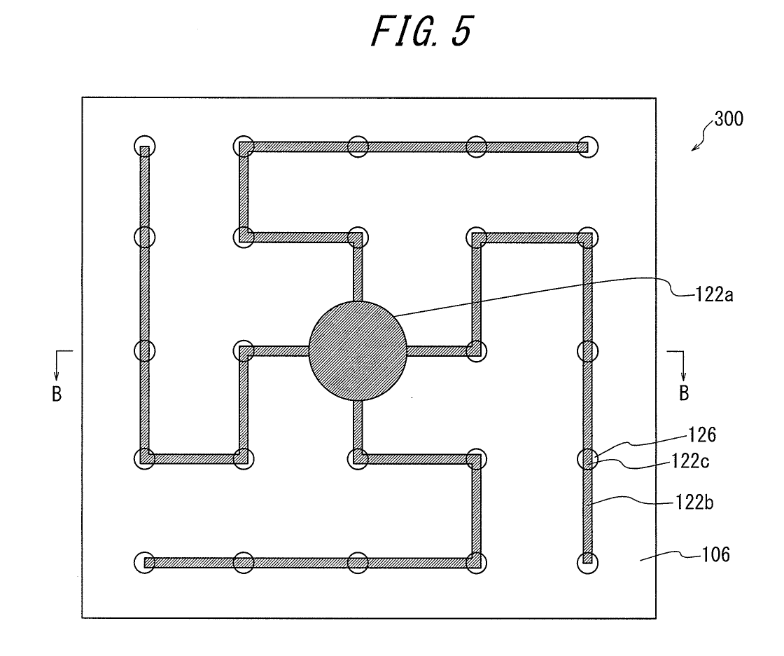

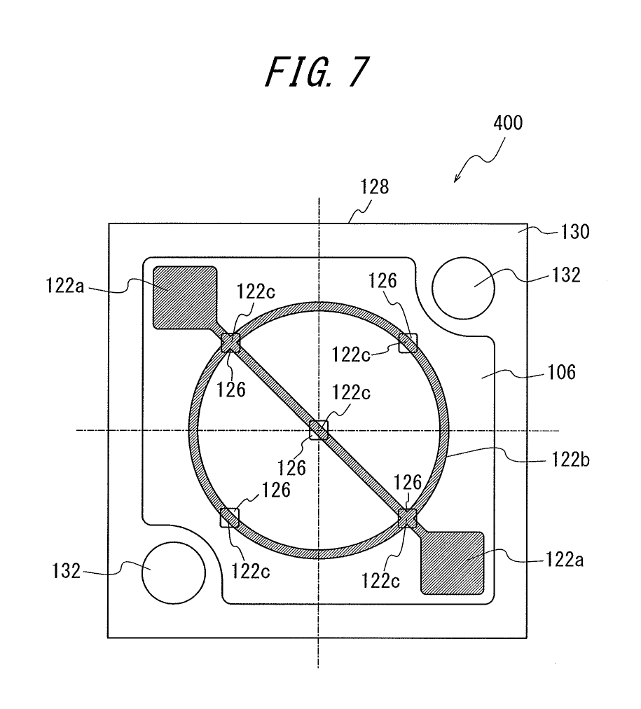

The exposed portions 126 and the contact portions 122c are not limited to the present embodiment, as long as a plurality of dispersed, independent portions are provided. So that current diffuses throughout the device without becoming concentrated, the number, positional relationships, shape, and size may be set freely in accordance with the shape of the device, the current applied, the arrangement of the electric pad that serves as a base point, and the value of internal resistivity of each semiconductor layer. For example, as in FIGS. 3 and 5, the contact portions 122c are preferably formed at positions equidistant from the pad portion 122a. Alternatively, as in FIG. 7, the resistance of the wiring portions 122b may be ignored, and the contact portions 122c may be formed at positions uniform with respect to the shape of the device. Since the n-side electrode 122 is in the direction of light extraction, however, a large electrode area adversely affects output. Therefore, the number of portions, positional relationships, shape, and size that achieve a balance between diffusing current and minimizing the area of the electrode are preferable.

Al, Cr, Ti, Ni, Pt, Au, or the like may be used as the electrode material for the n-side electrode 128. Since stable ohmic properties are easily achieved, a Ti/Al electrode is preferable and may, for example, be formed by a sputtering method.

Ni, Au, Pt, Pd, Rh, or the like is used in the p-side electrode 116. Since stable ohmic properties are easily achieved, an Ni/Au electrode is preferable and may, for example, be formed by sputtering. The p-side electrode 116 may be formed over the entire p-layer 112 or formed on a portion of the p-layer 112 by patterning.

While not illustrated, in order to provide mechanical strength when removing the substrate, a support substrate is preferably formed on the p-side electrode 116. The support substrate may be formed by wet or dry plating. For example, when electroplating with Cu or Au, as a connecting layer between the support substrate and the p-side electrode 116, Cu, Ni, Au, or the like may be used. A conductive silicon substrate, CuW alloy substrate, Mo substrate, or the like may be formed by bonding. In this case, as the bonding layer, for example Au, Sn, Zn, Cu, and alloys thereof may be used. An insulating substrate having high thermal conductivity, such as an MN sintered substrate, may be formed by bonding. In this case, it suffices to adopt a structure in which a conductive layer is provided on the insulating substrate and connected to the p-side electrode 116, and current is applied through the conductive layer. The conductive layer may also serve as the bonding layer, or a separate bonding layer may be formed.

The n-layer 108, light emitting layer 110, and p-layer 112 may, for example, be a III nitride semiconductor of AlGaN, GaN, or InAlGaN-based material, or the like. Examples of the p-type impurity include Mg, Zn, and C, and examples of the n-type impurity include Si, Te, and Se. The light emitting layer 110 may have a multiple quantum well (MQW) structure. In any of these cases, the layers may be grown epitaxially using a known method, such as MOCVD. The emission wavelength may be set to a range of 200 nm to 500 nm. The thickness of each layer may, for example, be as follows: n-layer 108, 0.5 μm to 5 μm; light emitting layer 110, 10 μm to 300 μm; p-layer 112, 0.1 μm to 2 μm. Up to this point, the first conductivity type has been described as being p-type and the second conductivity type as n-type in the present invention, yet the present invention is not limited in this way. The first conductivity type may of course be n-type, and the second conductivity type be p-type. In this case, the first electrode is the n-side electrode, and the second electrode is the p-side electrode.

The buffer layer 106 at least includes an undoped III nitride semiconductor layer used as a buffer layer formed on the lift-off layer before formation of the n-layer, light emitting layer, and p-layer. Undoped refers to not intentionally being doped with an impurity. Inevitable impurities due to the device, to diffusion, or the like may be included. The undoped III nitride semiconductor layer should be a semiconductor that does not function electrically as p-type or n-type, and it suffices to use a semiconductor with a low carrier concentration (for example less than 5×10¹⁶/cm³). In this way, the buffer layer overall has poor electric conductivity, and the buffer layer needs to be removed to expose the n-layer in order to obtain vertical electric conduction. Examples of preferable materials for the buffer layer 106 include undoped AlN, GaN, AlGaN, InGaN, InAlGaN, and the like. The thickness is preferably 200 nm to 2000 nm. The buffer layers 106 may be a single layer or may be a layered structure, such as a superlattice. In the present invention, in order to use the buffer layer 106 in the direction of light extraction while allowing the buffer layer 106 to remain, the buffer layer 106 preferably absorbs minimal light. Therefore, as the undoped III nitride semiconductor layer, AlN is most preferably used, since AlN has the largest bandgap energy among III nitride semiconductors and is transparent to a III nitride semiconductor light emitting device. Furthermore, it is preferred that the buffer layer 106 is an undoped layer, since a dopant could yield strain and become a light absorbing position. Using an undoped III nitride semiconductor layer as described above makes detachment from another III nitride semiconductor layer less likely than when using a separately formed insulating layer and furthermore yields the effect of reducing the number of processing steps.

III Nitride Semiconductor Light Emitting Device 200

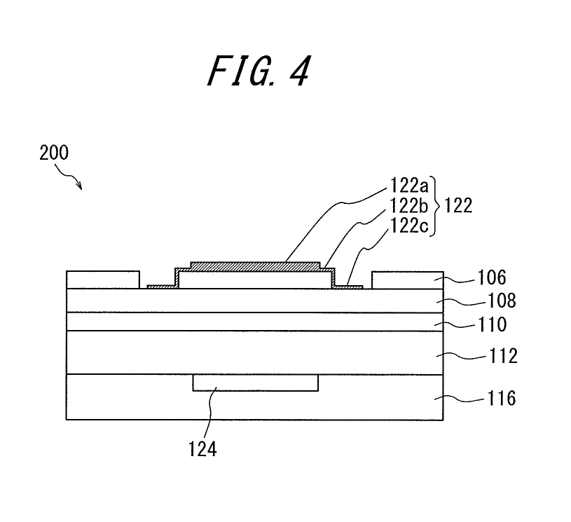

With reference to FIG. 4, the III nitride semiconductor light emitting device 200 according to another embodiment of the present invention is described below. The present embodiment is similar to the light emitting device 100 of Embodiment 1, except for including an insulating layer 124 positioned directly below the n-side electrode 122, specifically the pad portion 122a, on a portion of a surface of the p-layer 112. Instead of emitting light from the light emitting layer 110 directly below the n-side electrode 122, luminous efficiency increases by emitting light from other portions of the light emitting layer 110, since light cannot be extracted from the n-side electrode 122. Such an insulating layer 124 makes it difficult for current to flow to the light emitting layer directly below the n-side electrode 122 and easier for current to flow to other portions of the light emitting layer 110, thereby further increasing luminous efficiency.

The insulating layer 124 is preferably formed from SiO₂, SiN, Al₂O₃, or the like, and preferably has a thickness of 100 nm to 1000 nm. The above-described undoped III nitride semiconductor layer may be formed on the p-layer 112 and used as the insulating layer 124.

III Nitride Semiconductor Light Emitting Device 300

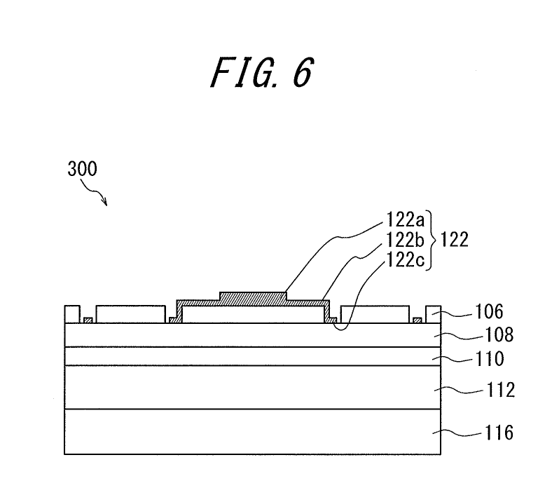

With reference to FIGS. 5 and 6, the III nitride semiconductor light emitting device 300 according to another embodiment of the present invention is described below. As illustrated in FIGS. 5 and 6, in the III nitride semiconductor light emitting device 300, numerous exposed portions 126 are formed on the buffer layer 106, and numerous contact portions 122c are formed. In the present embodiment, the n-side electrode 122 is formed by the numerous contact portions 122c, a pad portion 122a located in the center of the device, and wiring portions 122b connecting the contact portions 122c to the pad portion 122a. In this case as well, the contact portions 122c are electrically interconnected on the buffer layer 106. Thus providing numerous contact portions 122c uniformly over the entire device further improves the light output power and maintains the forward voltage low.

III Nitride Semiconductor Light Emitting Device 400

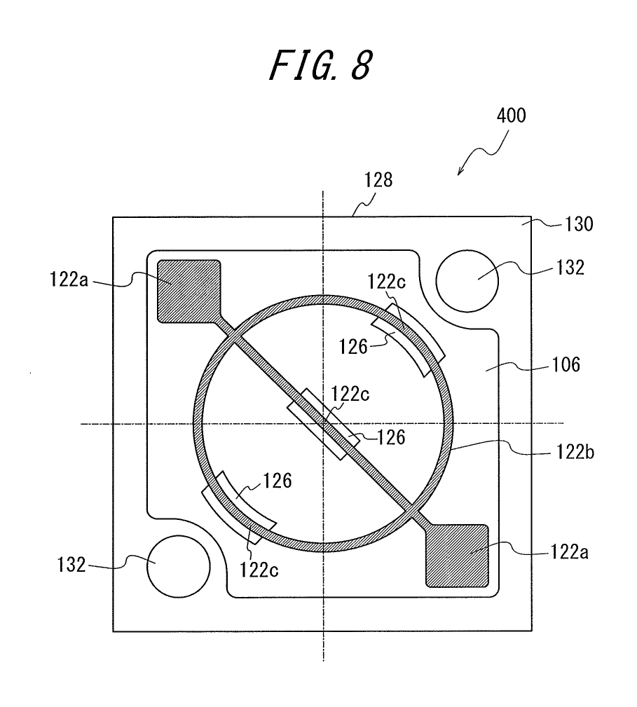

With reference to FIG. 7, the III nitride semiconductor light emitting device 400 according to another embodiment of the present invention is described below. In the III nitride semiconductor light emitting device 400, a conductive layer 130, p-side electrode, p-layer, light emitting layer, n-layer, and buffer layer 106 are formed in this order on an MN sintered substrate 128, which is a support substrate. As illustrated in FIG. 7, the buffer layer 106 has five exposed portions 126, which are portions where the n-layer is exposed. The n-side electrode is formed from contact portions 122c in contact with the exposed n-layer, a wiring portion 122b electrically connecting the contact portions 122c on the buffer layer 106 (including the sides), and pad portions 122a connecting to the wiring portion 122b. The wiring portion 122b has a doughnut shape connecting four contact portions 122c and a linear portion that passes through the contact portion 122c at the device center. The pad portions 122a are provided at two locations at opposite corners of the buffer layer 106. At the other set of opposite corners of the buffer layer 106, the conductive layer 130 on the AlN sintered substrate 128 is exposed, and p-side pad portions 132 are formed on the exposed conductive layer 130. The present embodiment also improves the light output power while reducing the forward voltage. The arrangement of the contact portions 122c may also be as in FIG. 8.

Method for Manufacturing III Nitride Semiconductor Light Emitting Device

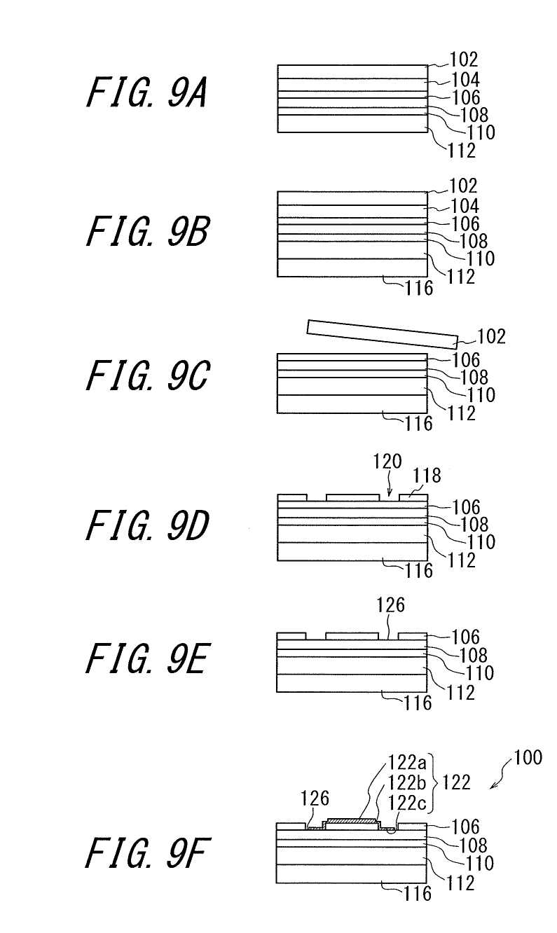

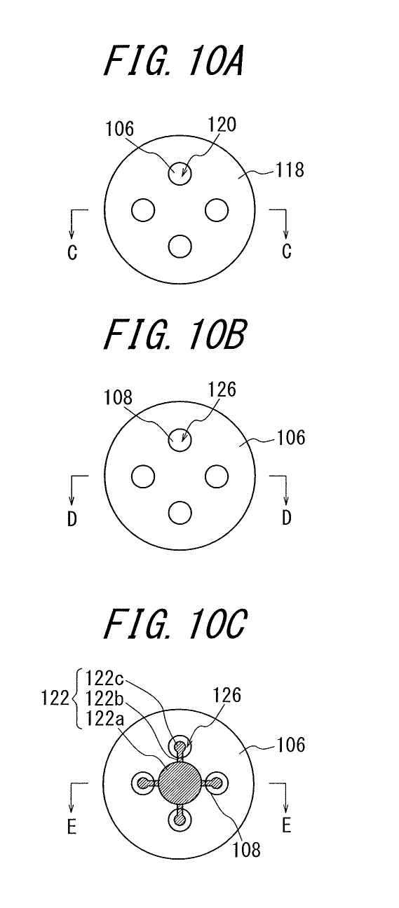

A method, according to the present invention, for manufacturing the III nitride semiconductor light emitting device 100 is described below with reference to FIGS. 9(A) to 9(F) and 10(A) to 10(C). FIG. 9(D) is a cross-sectional diagram along the C-C line in FIG. 10(A), and FIG. 9(E) is a cross-sectional diagram along the D-D line in FIG. 10(B). FIG. 9(F) is a cross-sectional diagram along the E-E line in FIG. 10(C).

First, as illustrated in FIG. 9(A), a lift-off layer 104 is formed on a growth substrate 102, and the buffer layer 106, n-layer 108, light emitting layer 110, and p-layer 112 are consecutively grown epitaxially, for example by MOCVD, on the lift-off layer 104. Subsequently, a step to form a groove in the p-layer, light emitting layer, n-layer, and buffer layer on the growth substrate and to remove a portion of the growth substrate may be included. When removing the growth substrate by separation using chemical liftoff, penetration of the etchant can be facilitated.

Next, as illustrated in FIG. 9(B), the p-side electrode 116 is formed on the p-layer 112. The p-side electrode 116 may be formed with the above-described materials and methods. While not illustrated, a support substrate may additionally be bonded onto the p-side electrode 116. As long as the p-side electrode is in contact with the p-layer 112 and has the function of supplying electricity, the p-side electrode is not limited to the above configurations.

Next, as illustrated in FIG. 9(C), by removing the lift-off layer 104 using the chemical lift-off method, the growth substrate 102 is separated from the buffer layer 106.

Next, as illustrated in FIG. 9(D), a mask 118 provided with openings 120 is formed on the buffer layer 106. A portion of the buffer layer 106 is exposed through each of the openings 120. As illustrated in FIG. 10(A), a plurality of the openings 120 is provided. The mask 118 is manufactured by forming an insulating film of SiO₂, SiN, or the like by, for example, plasma CVD and then, with a method such as reactive ion etching, removing only the portions where the openings are to be formed.

Next, as illustrated in FIG. 9(E), the surface of the buffer layer 106 exposed through the openings 120 is etched to form a plurality of exposed portions 126, in the buffer layer 106, that expose a portion of the n-layer 108. As illustrated in FIG. 10(B), the exposed portions 126 are formed in correspondence with the positions of the openings 120. Subsequently, the mask 118 is removed. At this time, as illustrated in FIG. 9(E), the entire mask 118 on the buffer layer 106 may be removed, or the mask 118 may be left on a portion of the buffer layer 106.

Next, as illustrated in FIG. 9(F) and FIG. 10(C), the n-side electrode 122 that is continuous on the n-layer 108 exposed by the exposed portions 126 and on the buffer layer 106 is formed by, for example, sputtering or vapor deposition. The n-side electrode 122 includes contact portions 122c in contact with the n-layer 108 in the exposed portions 126. The contact portions 122c are electrically interconnected by the wiring portions 122b and the pad portion 122a provided on the buffer layer 106. In order to form the n-side electrode in a predetermined region, pattering is performed by forming the n-side electrode after forming a resist pattern then using a lift-off method to remove the resist. After the resist pattern is formed, a method may be used to etch exposed portions with the resist pattern as a mask.

Between FIGS. 9(A) and 9(B), a step is preferably included to form an insulating layer on a portion of the surface of the p-layer 112 directly below a position where the n-side electrode 122 is to be provided. Doing so allows for manufacturing of a III nitride semiconductor light emitting device that includes the insulating layer 124 on the p-layer directly below the n-side electrode 122, as in FIG. 4. The insulating layer may be formed using plasma CVD, sputtering, a coating method, or the like. A method for forming an insulating film in a predetermined region is, for example, to form the insulating film and then etch exposed portions with the resist pattern as a mask. A method may also be used to perform patterning by forming a film after forming a resist pattern and then using a lift-off method to remove the resist.

For the growth substrate 102, a sapphire substrate or an AlN template substrate in which an AlN film is formed on a sapphire substrate is preferably used. The type of lift-off layer formed and the composition of the Al, Ga, or In semiconductor laminate formed from the III nitride semiconductor may be appropriately selected based on the quality, cost, and the like of the LED chip.

The lift-off layer 104 is not limited as long as a material that can be dissolved by the etchant is used. Examples include a non-group III metal or metal nitride buffer layer such as ScN or CrN.

Any etchant may be used in the chemical lift-off method. When the lift-off layer is CrN, an etchant that is selective with respect to CrN may be used, such as a ceric ammonium nitrate solution or a potassium permanganate-based solution. When the lift-off layer is ScN, Hf, or Zr, a selective acidic etchant may be used. The growth substrate 102 is not limited to being removed by the above method and may be separated by a laser lift-off method. In this case, the lift-off layer 104 need not be formed. The growth substrate 102 may also be removed by grinding or the like.

The method for etching the buffer layer 106 is not limited and may, for example, be wet etching with an alkaline solution such as TMAH, KOH, or NaOH, or dry etching such as reactive ion etching (RIE). In the case of RIE, when etching the nitride semiconductor, a gas of chlorine, silicon tetrachloride, boron trichloride, or the like may be used.

The present invention has only been described using representative embodiments as examples and is not limited to these embodiments. The present invention may be modified in a variety of ways within the scope thereof.

### EXAMPLES

To further clarify the effects of the present invention, the following describes a comparative evaluation of the Examples and Comparative Examples below.

### Production of III Nitride Semiconductor Light Emitting Device

### Example 1

The light emitting device illustrated in FIG. 1 was produced with the method illustrated in FIGS. 9(A) through 9(F). First, a 1 μm AlN layer was formed by MOCVD on the sapphire substrate as the growth substrate to yield an AlN template substrate. By sputtering, Cr (thickness: 8 nm) was formed thereon and nitriding treatment was applied in a MOCVD furnace using ammonium to form CrN as the lift-off layer. Subsequently, by MOCVD, III nitride semiconductor layers including a buffer layer (undoped AlN layer (thickness: 1 μm) and superlattice layer (AlN/GaN laminate, thickness: 1 μm)), n-layer (AlGaN layer, Si doped, thickness: 2 μm), light emitting layer (AlInGaN-based MQW layer, thickness: 0.2 μm, emission wavelength: 340 nm), and p-layer (AlGaN layer, Mg doped, thickness: 0.4 μm) were formed in this order.

Next, on the p-layer, Ni/Au (thickness: 10 nm/300 nm) was formed by sputtering to yield the p-side electrode. Subsequently, heat treatment was applied for 15 min at 600° C. Ti/Pt/Au was then formed by sputtering on the p-side electrode as a bonding layer. Ti/Pt/Au/Sn/Au was formed as a support substrate-side bonding layer on a separately prepared conductive Si substrate, and the two substrate bonding layers were pressed together and bonded by thermocompression for 60 min at 300° C. and a pressure of 6 MPa.

Subsequently, a chemical lift-off method was used to separate the sapphire substrate from the buffer layer. A ceric ammonium nitrate solution with selectivity for the CrN layer was used as the etchant.

Next, SiO₂ was formed by plasma CVD as a mask for the buffer layer, and using a resist pattern, portions were etched by BHF to form openings. As illustrated in FIG. 10(A), four independent openings with the same shape were formed concentrically at equal intervals. The size of the device was φ850 μm, the size of each opening was φ80 μm, and the center of each opening was positioned 180 μm from the center of the device.

Next, the buffer layer exposed through the openings in the SiO₂ was dry etched by RIE until a portion of the n-layer was exposed. As illustrated in FIG. 10(B), exposed portions with a similar shape to the shape of the openings in the mask surface were formed in the buffer layer. The mask was then removed.

Next, as illustrated in FIG. 10(C), an n-side electrode (Ti/Al, thickness: 20 nm/600 nm) was formed by sputtering. The pattern for the n-side electrode was created by forming a resist pattern, subsequently forming the n-side electrode in the openings of the resist pattern by sputtering, and removing the resist with a lift-off method. The n-side electrode included contact portions in contact with the exposed n-layer in the exposed portions. The contact portions each included a circular portion, concentric with the exposed portion, with a diameter of 65 μm and a linear portion, having a width of 20 μm and a length of approximately 7.5 μm, connecting to a wiring portion. The n-side electrode also included wiring portions electrically connecting the contact portions on the buffer layer (including the sides of the exposed portions) as well as a pad portion (diameter: 100 μm), in the center of the device, connecting the wiring portions. Furthermore, a pad electrode (Ti/Au, thickness: 20 nm/200 nm, diameter: 120 μm) was formed on the pad portion, aligned with the center thereof. Using a top view, the total area of the four contact portions was 13873 μm², and the area of the n-side electrode, including the pad electrode, was 31582 μm².

### Example 2

A similar light emitting device as in Example 1 was produced, except that after forming the p-layer and before forming the p-side electrode, an insulating layer (thickness: 300 nm, diameter: 120 μm) constituted by SiO₂ was formed by plasma CVD on the surface of the p-layer to be directly below and concentric with the planned location for forming the pad portion of the n-side electrode.

### Comparative Example 1

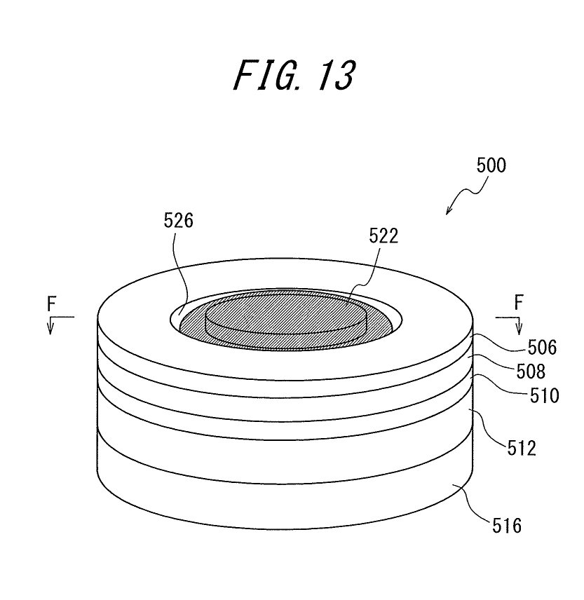

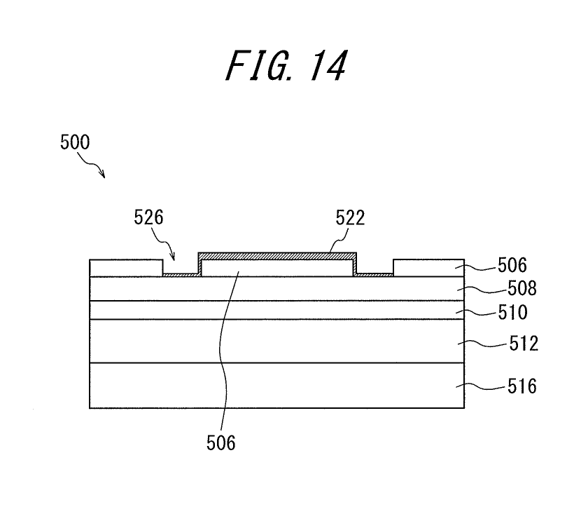

A III nitride semiconductor light emitting device 500 as illustrated in FIGS. 13 and 14 was produced to be similar to Example 1, except for modifying the shape of the opening in the mask, i.e. the shape of the exposed portion formed in the buffer layer, and the shape of the n-side electrode as described below. In this device, an exposed portion 526 in a continuous doughnut shape with an outer diameter of 200 μm and an inner diameter of 150 μm was formed in the buffer layer 506. An n-side electrode 522 (diameter: 200 μm) was formed on an exposed n-layer 508 and on the surrounded buffer layer 506 in the hole. In other words, the n-side electrode included a contact portion with the same doughnut-shape as the exposed portion 526 and a wiring/pad portion, in the center of the device, connected to the contact portion and having a diameter of 150 μm. In this Comparative Example, the contact portion between the n-side electrode and the n-layer was one continuous doughnut-shaped region. Using a top view, the area of the contact portion was 13744 μm², and the area of the n-side electrode was 31425 μm², nearly the same as in the Examples.

### Comparative Example 2

A similar light emitting device as in Comparative Example 1 was produced, except that after forming the p-layer and before forming the p-side electrode, an insulating layer similar to that of Example 2 was formed on the surface of the p-layer.

Evaluation Method

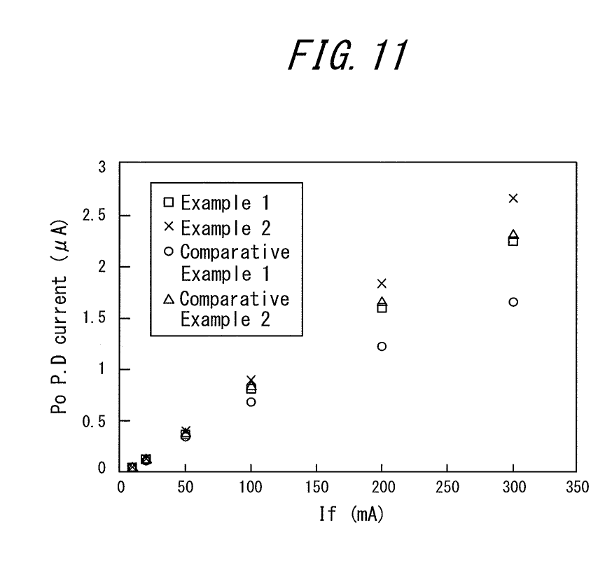

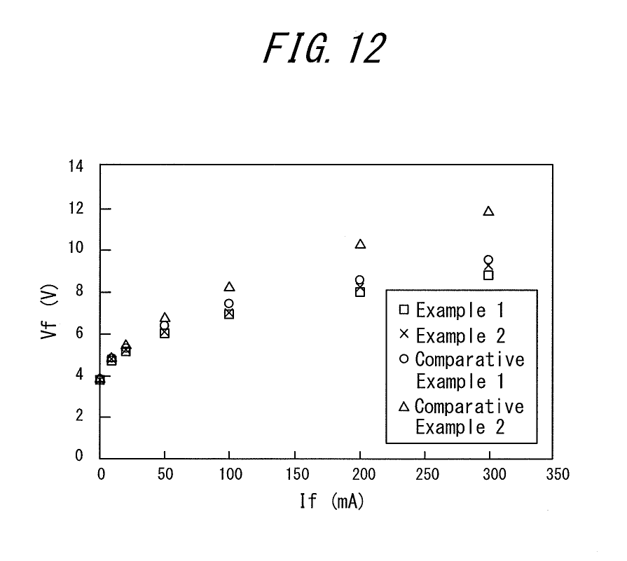

Wire bonding was performed in the pad portions of the light emitting devices of Examples 1 and 2 and Comparative Examples 1 and 2. When applying a predetermined current from 0 mA to 300 mA to the resulting light emitting devices using a constant current constant voltage power supply, the light output power Po and forward voltage Vf, respectively shown in FIGS. 11 and 12, were evaluated by the current of a photodiode disposed above the buffer layer side of each of the devices.

Evaluation Results

As shown in FIGS. 11 and 12, the light output power Po was lower for Comparative Example 1 than for the other Examples. Comparative Example 2 yielded a higher light output power Po than Comparative Example 1 due to the insulating layer provided directly below the pad portion. The forward voltage Vf, however, was higher than for the other Examples. On the other hand, Examples 1 and 2 had a high light output power Po and low forward voltage Vf. The reason is thought to be that Examples 1 and 2 had a plurality of contact portions between the n-side electrode and the n-layer.

### INDUSTRIAL APPLICABILITY

According to the present invention, a III nitride semiconductor light emitting device that achieves improved light output power while reducing forward voltage and a method for manufacturing the same are provided.

### REFERENCE SIGNS LIST

100: III nitride semiconductor light emitting device
102: Growth substrate
104: Lift-off layer
106: Buffer layer
108: N-type III nitride semiconductor layer
110: Light emitting layer
112: P-type III nitride semiconductor layer
116: P-side electrode
118: Mask
120: Opening
122: N-side electrode
122a: Pad portion
122b: Wiring portion
122c: Contact portion
124: Insulating layer
126: Exposed portion
200: III nitride semiconductor light emitting device
300: III nitride semiconductor light emitting device
400: III nitride semiconductor light emitting device

1. A III nitride semiconductor light emitting device comprising:
a first electrode;
a first conductivity type III nitride semiconductor layer connected to the first electrode;
a light emitting layer provided on the first conductivity type III nitride semiconductor layer;
a second conductivity type III nitride semiconductor layer provided on the light emitting layer;
a buffer layer including an undoped III nitride semiconductor layer provided on the second conductivity type III nitride semiconductor layer; and
a second electrode including a plurality of independent contact portions and electrically connecting the contact portions, the contact portions being in contact with the second conductivity type III nitride semiconductor layer exposed by removing a portion of the buffer layer,
a portion of the second electrode being provided on the buffer layer.

2. The III nitride semiconductor light emitting device according to claim 1, wherein the undoped III nitride semiconductor layer is an AlN layer.

3. The III nitride semiconductor light emitting device according to claim 1, wherein the second electrode includes the contact portions, a pad portion provided on the buffer layer, and a wiring portion connecting the contact portions and the pad portion.

4. The III nitride semiconductor light emitting device according to claim 3, further comprising an insulating layer positioned directly below the second electrode on a portion of a surface of the first conductivity type III nitride semiconductor layer facing the first electrode.

5. A method for manufacturing a III nitride semiconductor light emitting device, the method comprising:
(a) forming, sequentially on a growth substrate, a buffer layer containing an undoped III nitride semiconductor layer, a second conductivity type III nitride semiconductor layer, a light emitting layer, and a first conductivity type III nitride semiconductor layer;
(b) forming a first electrode on the first conductivity type III nitride semiconductor layer;
(c) removing the growth substrate to expose the buffer layer;
(d) removing a portion of the buffer layer exposed in step (c) to expose a portion of the second conductivity type III nitride semiconductor layer; and
(e) forming a second electrode continuously on the second conductivity type III nitride semiconductor layer exposed in step (d) and the buffer layer,
the second electrode including a plurality of independent contact portions and electrically connecting the contact portions, the contact portions being in contact with the second conductivity type III nitride semiconductor layer.

6. The method according to claim 5, wherein the undoped III nitride semiconductor layer is an AlN layer.

7. The III nitride semiconductor light emitting device according to claim 2, wherein the second electrode includes the contact portions, a pad portion provided on the buffer layer, and a wiring portion connecting the contact portions and the pad portion.
